(19) United States
(12) Patent Application Publication
(10) Pub. No.: US 2017/0338343 A1
(43) Pub. Date: Nov. 23, 2017

(54) HIGH-VOLTAGE TRANSISTOR DEVICE

(71) Applicant: GLOBALFOUNDRIES Inc., Grand Cayman (KY)

(72) Inventors: Sylvain Henri Baudot, Dresden (DE); Gunter Grasshoff, Radebeul (DE); Juergen Faul, Radebeul (DE); Peter Javorka, Radeburg (DE)

(21) Appl. No.: 15/161,604

(22) Filed: May 23, 2016

(51) Int. Cl. H01L 29/78; H01L 29/06; H01L 27/092; H01L 21/8238; H01L 21/84; H01L 29/08; H01L 27/12

(52) U.S. Cl. CPC H01L 29/7838; H01L 29/0847; H01L 29/0649; H01L 27/1203; H01L 21/823814; H01L 21/84; H01L 21/823892; H01L 27/0928

(57) ABSTRACT

A semiconductor device is provided comprising a silicon-on-insulator (SOI) substrate comprising a semiconductor bulk substrate, a buried oxide layer formed on the semiconductor bulk substrate and a semiconductor layer formed on the buried oxide layer and a transistor device, wherein the transistor device comprises a gate electrode formed by a part of the semiconductor bulk substrate, a gate insulation layer formed by a part of the buried oxide layer and a channel region formed in a part of the semiconductor layer.

### BACKGROUND

### 1. Field of the Disclosure

Generally, the subject matter disclosed herein relates to integrated circuits, and, more particularly, to transistor devices, in particular, field effect transistor devices with (super) low/zero threshold-voltage allowing for a high-voltage operation.

### 2. Description of the Related Art

Integrated circuits formed on semiconductor wafers typically include a large number of circuit elements, which form an electric circuit. In addition to active devices such as, for example, field effect transistors and/or bipolar transistors, integrated circuits can include passive devices, such as resistors, inductors and/or capacitors. In particular, during the fabrication of complex integrated circuits using CMOS technology, millions of transistors, i.e., N-channel transistors and P-channel transistors, are formed on a substrate including a crystalline semiconductor layer.

A MOS transistor, for example, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed near the channel region and separated therefrom by a thin insulating layer. The conductivity of the channel region, upon formation of a conductive channel due to the application of an appropriate control voltage to the gate electrode, depends on, among other things, the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the overall conductivity of the channel region substantially determines the performance of the MOS transistors.

For rectifying and/or switching applications, for example, high-voltage (i.e., high supply voltage) transistors sustaining high supply voltages (V_{DD}) are needed. The development of single chip processes for integrating power switches with control circuitry is a major trend in the field of power IC development. For example, the LDMOS (lateral double diffusion MOS) process is currently being applied to manufacture monolithic ICs. For example, an LDMOS FET, as a device of MOSFET variety, is a key component of an RF power amplifier used in base stations for personal communication systems (for example, GSM, EDGE, etc.). High breakdown-voltages are most important advantages of LDMOS FETs. However, LDMOS FETs cannot easily be integrated in the process of manufacturing (MOS) FETs within the Fully Depleted Silicon-on Insulator (FDSOI) approach. On the other hand, usual MOS FETs produced according to the Fully Depleted Silicon-on-Insulator (FDSOI) approach do not sustain high supply voltages (for example, V_{DD}>1.8 V) due to a breakdown of thin spacers and or gate oxide degradation.

FIG. 1a illustrates a typical FDSOI field effect transistor (FET) 100 formed on an SOI substrate comprising a semiconductor substrate 101, a buried oxide layer 102 and a semiconductor layer 103. The FDSOI FET 100 may be manufactured on a 22 nm node and comprises a gate electrode 104, a raised source 105 and a raised drain 106, as well as a gate dielectric 107. Spacers 108 are formed on sidewalls of the gate electrode 104. The FDSOI FET 100 is suitable for operation at supply voltages below 1.8 V. However, in practice, a supply voltage of larger than 3 V is needed in particular applications, for example, high-frequency switching operations. If a voltage of, say, 3.3 V is applied to the gate electrode 104 and the drain 106 (with the source 105 being connected to ground), breakdown of the thin gate dielectric 107 and the thin spacers 108 occurs and operation of the FDSOI FET 100 is deteriorated or the FDSOI FET 100 fails operating at all.

There are approaches known in the art to co-integrate high-voltage transistor devices in the process flow of manufacturing FDSOI FETs, as, for example, the FDSOI FET 100 shown in FIG. 1a. FIG. 1b shows an example of a semiconductor device comprising a P-channel FDSOI FET 110 (similar to the FDSOI FET 100 shown in FIG. 1a) and a P-channel high-voltage FET 120. Manufacturing starts from provision of an SOI substrate comprising a semiconductor bulk substrate 111, a buried oxide layer 112 and a semiconductor layer 113. The P-channel FDSOI FET 110 comprises a gate electrode 114, a raised source 115 and a raised drain 116, as well as a gate dielectric 117. A multilayer insulation structure 118 comprising spacers formed on sidewalls of the gate electrode 114 is provided. Moreover, a silicide layer 119 is formed on surfaces of the gate electrode 114, raised source 115 and raised drain 116 to enhance electrical contact properties.

The high-voltage FET 120 cannot be formed as an FDSOI device for the above-described reasons. Rather, the high-voltage FET 120 has to be formed as a bulk device with a channel region formed in the semiconductor bulk substrate 111. The high-voltage FET 120 comprises a gate electrode 124. A source region 125 as well as a drain region 126 are formed in the semiconductor bulk substrate 111 by appropriate doping. A multilayer spacer structure 128 is provided and the gate electrode 124 and the source and drain regions 125, 126 are silicided by the formation of a silicide layer 129 that may be formed together with silicide layer 119 in a single process.

However, co-integration of the high-voltage FET 120 with the FDSOI FET 110 involves many separate masking and depositing steps, in particular, dual oxide and spacer processing schemes with several additional masks as compared to the pure FDSOI processing.

In view of the above, the present disclosure relates to transistor devices and techniques for forming transistor devices allowing for high-frequency, high-voltage operation with high reliability that can be integrated in the process flow of FDSOI manufacturing without enhancing the complexity of the manufacturing process in terms of additional deposition and masking steps.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to semiconductor devices and methods for fabricating the same, wherein enhanced transistor performance may be obtained for N-channel transistors and P-channel transistors on the basis of Fully Depleted Silicon-on-Insulator (FDSOI) techniques. Particularly, high-voltage FETs allowing supply voltages of above 2.5 or 3 V, for example, are provided that can be manufactured in a co-integrated manner within a process flow of manufacturing FDSOI FETs.

One illustrative semiconductor device disclosed herein comprises a silicon-on-insulator (SOI) substrate comprising a semiconductor bulk substrate, a buried oxide layer formed on the semiconductor bulk substrate and a semiconductor layer formed on the buried oxide layer and a transistor device, wherein the transistor device comprises a gate electrode formed (in or) by a part of the semiconductor bulk substrate, a gate insulation layer formed (in or) by a part of the buried oxide layer and a channel region formed in (or by) a part of the semiconductor layer.

Furthermore, a semiconductor device is provided comprising a silicon-on-insulator (SOI) substrate comprising a semiconductor bulk substrate, a buried oxide layer formed on the semiconductor bulk substrate and a semiconductor layer formed on the buried oxide layer, a first transistor device, for example, an FDSOI FET, comprising a first gate electrode formed over the semiconductor layer and a first gate dielectric, for example, comprising a high-k (k>5, for example) dielectric material, formed between the first gate electrode and the semiconductor layer, and a second (high-voltage) transistor device comprising a second gate electrode formed in (or by part of) the semiconductor bulk substrate and a second gate dielectric formed in (or by part of) the buried oxide layer.

One illustrative method of forming a semiconductor device disclosed herein includes providing a silicon-on-insulator (SOI) substrate comprising a semiconductor bulk substrate, a buried oxide layer formed on the semiconductor bulk substrate and a semiconductor layer formed on the buried oxide layer and forming a first transistor device in and on the SOI substrate including the steps of forming a first gate insulation layer on the semiconductor layer and forming a first gate electrode on the first gate insulation layer. The method further includes forming a second transistor device in the SOI substrate including the steps of forming a second gate electrode in (or by part of) the semiconductor bulk substrate and forming a second gate insulating layer in (or by part of) the buried oxide layer. In particular, the first transistor device may be a low-voltage FDSOI FET and the second transistor device may be a high-voltage transistor. The second transistor may be a low threshold-voltage or a super low-threshold voltage transistor operable at relatively high voltages (for example, with a supply voltage higher than 2.5 or 3 V).

The thus manufactured or provided transistor may be used as a switching device in high-frequency applications. A method of driving a semiconductor device (transistor device) is also provided, wherein the semiconductor device comprises a silicon-on-insulator (SOI) substrate comprising a semiconductor bulk substrate, a buried oxide layer formed on the semiconductor bulk substrate and a semiconductor layer formed on the buried oxide layer and a transistor device, wherein the transistor device comprises a gate electrode formed (in or) by a part of the semiconductor bulk substrate, a gate insulation layer formed (in or) by a part of the buried oxide layer and a channel region formed in (or by) a part of the semiconductor layer, source and drain regions, for example, formed over the semiconductor layer, an upper electrode formed over the semiconductor layer and sidewall spacers formed between the source and drain regions and the upper electrode. This method includes applying a first electrical voltage of more than 2 V (for example, more than 2.5 V or 3 V or in a range of 2-3.6 V) to the gate electrode, applying a second electrical voltage of the same value as the first electrical voltage to the drain region, applying a third electrical voltage of less than 2 V (for example, about 1.8 V) to the upper electrode, and connecting the source region to ground.

### BRIEF DESCRIPTION OF THE DRAWINGS

The disclosure may be understood by reference to the following description taken in conjunction with the accompanying drawings, in which like reference numerals identify like elements, and in which:

FIG. 1a illustrates an FDSOI FET of the prior art;

FIG. 1b illustrates a semiconductor device comprising an FDSOI FET and a high-voltage FET of the prior art;

FIG. 2 illustrates a high-voltage FET device according to an illustrative example of the present disclosure;

FIG. 3 illustrates a semiconductor device comprising a low threshold voltage-high supply voltage FET device according to an illustrative example of the present disclosure; and

FIG. 4 illustrates a semiconductor device comprising a super low threshold voltage-high supply voltage FET device according to an example of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As used herein, spatial references “top,” “bottom,” “upper,” “lower,” “vertical,” “horizontal” and the like may be used for convenience when referring to structures of FET devices. These references are intended to be used in a manner consistent with the drawings only for teaching purposes, and are not intended as absolute references for FET structures. For example, FETs may be oriented spatially in any manner different from the orientations shown in the drawings. “Vertical” is used to refer to a direction normal to the semiconductor layer surface, and “horizontal” is used to refer to a direction parallel to the semiconductor layer surface when referring to the drawings. “Upper” is used to refer to a vertical direction away from the semiconductor layer. An element positioned “above” (“below”) another one is located farther away from (closer to) the semiconductor layer surface as compared to the other one.

As will be readily apparent to those skilled in the art upon a complete reading of the present application, the present method is applicable to a variety of technologies, for example, NMOS, PMOS, CMOS, etc., and is readily applicable to a variety of devices, including, but not limited to, logic devices, memory devices, SRAM devices, etc., in principle. The techniques and technologies described herein may be utilized to fabricate MOS integrated circuit devices, including NMOS integrated circuit devices, PMOS integrated circuit devices, and CMOS integrated circuit devices. In particular, the process steps described herein are utilized in conjunction with any semiconductor device fabrication process that forms gate structures for integrated circuits, including both planar and non-planar integrated circuits. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor bulk substrate.

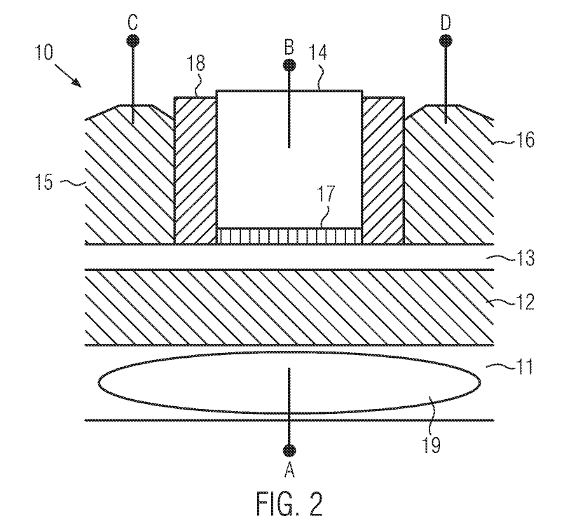

Generally, a high-voltage transistor device with (super) low threshold voltage and how to manufacture and operate a semiconductor device with such a transistor device allowing for relatively high supply voltages (high-voltage operation) is described. With reference to FIGS. 2, 3 and 4 illustrative embodiments will now be described in more detail.

As shown in FIG. 2, a semiconductor device according to the present disclosure comprises a FET device 10 formed on an SOI substrate, in particular, an FDSOI substrate. The FET device 10 may be a MOSFET. The SOI substrate comprises a semiconductor bulk substrate 11, a buried oxide (BOX) layer 12 formed on the semiconductor bulk substrate 11 and a semiconductor layer 13 (active layer) formed on the BOX layer 12. The semiconductor layer 13 may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon, silicon/germanium, silicon/carbon, other II-VI or III-V semiconductor compounds and the like.

The BOX layer 12 may comprise silicon (di)oxide or a borosilicate glass or a borophosphosilicate glass (BPSG). The BOX layer may be composed of different layers and one of the different layers may comprise BPSG or an SiO₂-compound comprising boron or phosphorus. The semiconductor bulk substrate 11 may comprise or consist of silicon, in particular, single crystal silicon. Other materials may be used to form the semiconductor bulk substrate 11 such as, for example, germanium, silicon germanium, gallium phosphate, gallium arsenide, etc. The thickness of the semiconductor layer 13 may be in a range of 5-30 nm, in particular, 5-15 nm, and the thickness of the BOX layer 12 may be in a range of 10-50 nm, in particular, 10-30 nm and, more particularly, 15-25 nm.

Shallow trench isolation (STI) regions (not shown in FIG. 2) may be formed in the SOI substrate in order to electrically isolate the transistor device 10 from other electric components of an IC formed on the SOI substrate. The STI regions may be formed by etching openings through the semiconductor layer 13 and the BOX layer 12 and in the semiconductor bulk substrate 11 and filling the opening by some insulating material, for example, some oxide material.

The FET device 10 comprises an upper electrode 14, a source 15 and a drain 16. The upper electrode 14 is separated from the semiconductor layer 13 by a gate dielectric 17. Sidewall spacers 18 are formed on sidewalls of the upper electrode 14. The upper surfaces of the upper electrode 14 and the source 15 and the drain 16 may be silicided. Silicidation may comprise deposition of an NiPt, Ni or Co layer on the surfaces of the raised semiconductor regions 15 and 16 and the upper surface of the upper gate 14 and performing one or more thermal anneal processes. The resulting silicided regions provide for low-resistance contacts.

The upper electrode 14 may comprise a polysilicon layer and/or a metal-containing layer. The metal-containing layer may comprise at least one of titanium nitride (TiN), tantalum nitride (TaN), tantalum (Ta), tungsten (W), for example. The metal-containing layer may be relatively thin with a thickness below 50 nm, in particular below 20 nm. The upper electrode 14 may comprise a semiconductor layer, for example, comprising silicon, for example, undoped polycrystalline silicon, above a metal-containing layer. The semiconductor layer of the gate electrode material may comprise undoped polycrystalline silicon. A work function adjusting layer may be provided between a metal gate layer of the upper electrode 14 and the gate dielectric 17.

The gate dielectric 17 may comprise or consist of a high-k material, for example, with a dielectric constant k>5. The high-k material may comprise a transitional metal oxide, such as at least one of hafnium oxide, hafnium dioxide and hafnium silicon-oxynitride. According to some exemplary embodiments, the (high-k) dielectric layer 17 may be formed directly on the semiconductor layer 13. According to other embodiments the (high-k) dielectric layer 17 may be formed on an insulating layer (not shown) comprising silicon oxide which is formed on the semiconductor layer 13. The work function adjusting layer may comprise titanium nitride (TiN) or any other appropriate work function adjusting metal or metal oxide that is known in the art,

The side spacers 18 may include silicon dioxide and they may be provided in the form of a multilayer by subsequently epitaxially growing or depositing the respective layers of the gate structure and appropriately etching them.

The source and drain electrodes 15 and 16 may be formed from a semiconductor layer, for example, a semiconductor layer comprising silicon, by (selective) epitaxy. Thereby, the raised source and drain regions 15 and 16 are formed adjacent to the sidewall spacers 18. The raised source and drain regions 15 and 16 may have thicknesses in the range of 20-50 nm, for example.

It is noted that there are basically two well-known processing methods for forming a planar or 3D transistor with a high-k metal gate (HKMG) structure. In the replacement gate technique, a so-called “dummy” or sacrificial gate structure is initially formed and remains in place as many process operations are performed to form the device, for example, the formation of doped source/drain regions, performing an anneal process to repair damage to the substrate caused by the ion implantation processes and to activate the implanted dopant materials. At some point in the process flow, the sacrificial gate structure is removed to define a gate cavity where the final HKMG gate structure for the device is formed. Using the “gate first” technique, on the other hand, involves forming a stack of layers of material across the substrate, wherein the stack of materials includes a high-k gate insulation layer, one or more metal layers, a layer of polysilicon, and a protective cap layer, for example, silicon nitride. One or more etching processes are performed to pattern the stack of materials to thereby define the basic gate structures for the transistor devices. Both the replacement gate process flow and the gate first process flow may be employed in accordance with the present disclosure.

According to the disclosure, the FET device 10 comprises a (front) gate electrode 19 that is formed in the semiconductor bulk substrate 11 and contacted by contact A. The (front) gate electrode 19 may be formed by a part of the semiconductor bulk substrate 11, i.e., the semiconductor bulk substrate 11 may function as the (front) gate electrode 19. The upper electrode 14 is contacted by contact B, the source electrode 15 is contacted by contact C and the drain electrode 16 is contacted by contact D (see FIG. 2). A supply voltage higher than 2 V, in particular, higher than 3 V, can be applied to contacts A and D and thereby to the front gate electrode 19 and the drain electrode 16, and contact C and thereby the source electrode 15 may be contacted to ground.

According to alternative examples, the upper electrode 14 may be maintained in a floating state (floating upper electrode 14) or a voltage may be applied through contact B to the upper electrode 14, thereby allowing for dual gate control of the operation of the FET device 10. The dual gate control allows for obtaining desirable strengths of the on current. If a finite voltage is applied to the upper electrode 14 such that the upper electrode 14 functions as a back electrode, it must be observed that the voltage drop between the upper electrode 14 and the source 15 as well as the voltage drop between the upper electrode 14 and the drain 16 has to be low enough in order to prevent breakdown of the spacers 18. If, for example, 3.6 V is applied to the drain electrode 16 and the front gate electrode 19, the voltage applied to the upper electrode 14 must not exceed 3.6 V-1.8 V if breakdown occurs for a voltage drop above 1.8 V.

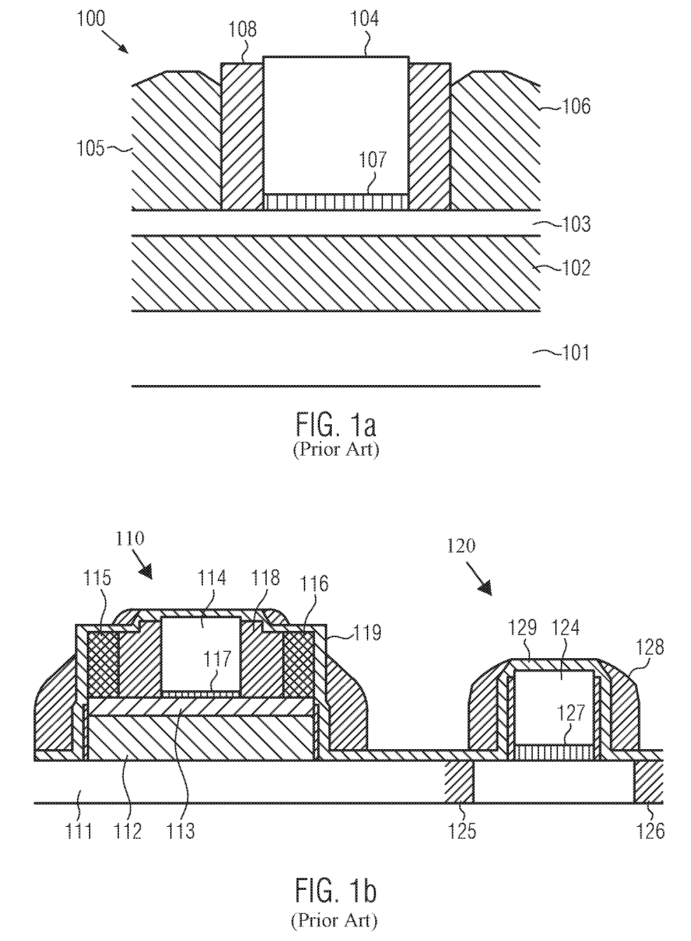

In the configuration illustrated in FIG. 2, the relatively thick BOX layer 12 is used for both a gate oxide (gate dielectric) for the front gate electrode 19 and electrical insulation of the front gate electrode 19 formed in the semiconductor bulk substrate 11 from the source electrode 15 and the drain electrode 16. Thus, the problem of a breakdown of a gate dielectric similar to the gate dielectric 17 shown in FIG. 2 and breakdown of spacers similar to the sidewall spacers 18 shown in FIG. 2 can be avoided. In particular, the formation of a high-voltage FET, as the FET device 10 shown on FIG. 2, can be readily integrated in the process flow for manufacturing FDSOI (MOS)FETs, for example, single gate or extended gate FETS, that are suitably used for relatively low-voltage (for example, <1.8 V) operation. For example, the transistor device shown in FIG. 2 can be co-manufactured with a transistor device as the one shown in FIG. 1a and a back gate of the transistor device shown in FIG. 2 can be formed of the same material and/or in the same manufacturing process as used for the formation of the gate electrode 104 of the transistor device 100 shown in FIG. 1a.

It is noted that fine tuning of high-voltage devices similar to the one shown in FIG. 2 can be achieved by appropriately doping the semiconductor bulk substrate 11 in different regions. For example, the drain saturation current can be adjusted by an appropriate well formation and/or selection of the work functions involved.

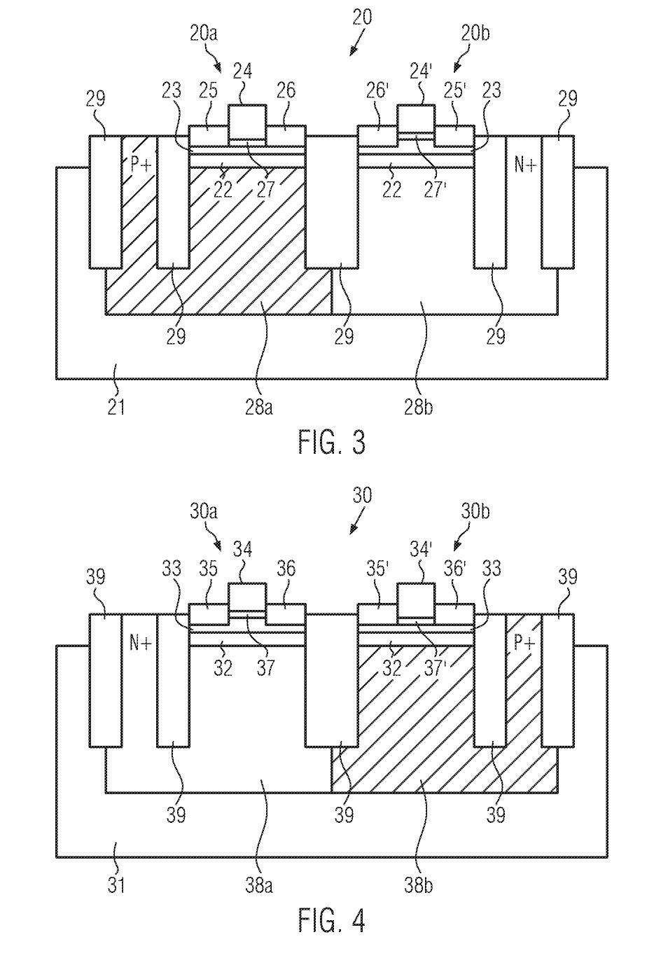

FIG. 3 illustrates a semiconductor device 20 comprising a low threshold voltage FET device allowing for high-voltage operation in accordance with the present disclosure. The semiconductor device 20 comprises an N-channel FET 20a and a p-channel FET 20b. The N-channel FET 20a and the P-channel FET 20b are formed on an FDSOI substrate comprising a semiconductor bulk substrate 21, a buried oxide layer (BOX) layer 22 formed on the semiconductor bulk substrate 21 and a semiconductor layer 23 (active layer) formed on the BOX layer 22. Channel regions are formed in the semiconductor layer 22. The N-channel FET 20a and the P-channel FET 20b may be extended gate devices, for example, comprising gate electrodes extending to the semiconductor bulk substrate 21 or the BOX layer 22 outside a region shown in FIG. 3. The same materials for the different layers of the SOI substrate can be chosen as mentioned in the context of the description of FIG. 2. In particular, the semiconductor layer 23 may be a crystalline silicon layer.

Both the N-channel FET 20a and the P-channel FET 20b comprise, respectively, an upper electrode 24, 24′, a source electrode 25, 25′ and a drain electrode 26, 26′. The upper electrodes 24, 24′ are separated by from the semiconductor layer 23 by gate dielectrics 27, 27′. Again, the materials mentioned in the context of the description of FIG. 2 can also be used for the corresponding layers shown in FIG. 3. Particularly, the upper electrodes 24, 24′ may comprise metal gate layers and/or polysilicon gate layers and the gate dielectrics 27, 27′ may represent high-k dielectrics with a dielectric constant larger than the one of silicon dioxide, for example, k>5.

A P-well 28a is formed by appropriate doping in the semiconductor bulk substrate 21 below the N-channel FET 20a and, accordingly, an N-well 28b is formed by appropriate doping in the semiconductor bulk substrate 21 below the P-channel FET 20b. Moreover, STIs 29 are formed in the semiconductor bulk substrate 21 (and through the semiconductor layer 23 and the BOX layer 22). The part of the P-well 28a that is isolated by the STIs 29 may have a P⁺ doped upper region. Accordingly, the part of the N-well 28b that is isolated by the STIs 29 may have an N⁺ doped upper region.

Similar to the example described with reference to FIG. 2, part of the semiconductor bulk substrate 21 of the semiconductor device 20 shown in FIG. 3 can be used as a front gate electrode for the N-channel FET 20a and the P-channel FET 20b. The upper electrodes 24 and 24′ may be floating or may be used as back gates for dual operation control. The sources 25, 25′ and the upper P⁺ region of the isolated part of the P-well and the upper N⁺ region of the isolated part of the N-well may be connected to ground. In operation, a relatively high supply voltage of 3.6 V or more may be applied to the drains 26, 26′ and the front gate electrodes formed by parts of the semiconductor bulk substrate 21.

FIG. 4 illustrates a semiconductor device 30 comprising a super low threshold voltage FET device allowing for high-voltage operation in accordance with the present disclosure. The semiconductor device 30 comprises an N-channel FET 30a and a P-channel FET 30b. The N-channel FET 30a and the P-channel FET 30b are formed on an FDSOI substrate comprising a semiconductor bulk substrate 31, a buried oxide layer (BOX) layer 32 formed on the semiconductor bulk substrate 31 and a semiconductor layer 33 (active layer) formed on the BOX layer 32. The N-channel FET 30a and the P-channel FET 30b may be extended gate devices with gate electrodes extending to the semiconductor bulk substrate 31 or the BOX layer 32 outside a region shown in FIG. 4. The same materials for the different layers of the SOI substrate can be chosen as mentioned in the context of the description of FIG. 2. In particular, the semiconductor layer 33 may be a crystalline silicon layer.

Both the N-channel FET 30a and the P-channel FET 30b comprise, respectively, an upper electrode 34, 34′, a source electrode 35, 35′ and a drain electrode 36, 36′. The upper electrodes 34, 34′ are separated from the semiconductor layer 33 by gate dielectrics 37, 37′. Again, the materials mentioned in the context of the description of FIG. 2 can also be used for the corresponding layers shown in FIG. 4.

An N-well 38a is formed by appropriate doping in the semiconductor bulk substrate 31 below the N-channel FET 30a and, accordingly, a P-well 38b is formed by appropriate doping in the semiconductor bulk substrate 31 below the P-channel FET 30b. Moreover, STIs 39 are formed in the semiconductor bulk substrate 31 (and through the semiconductor layer 33 and the BOX layer 32). The part of the N-well 38a that is isolated by the STIs 39 may have an N⁺ doped upper region. Accordingly, the part of the P-well 38b that is isolated by the STIs 39 may have a P⁺ doped upper region.

Similar to the example described with reference to FIG. 2, part of the semiconductor bulk substrate 31 of the semiconductor device 30 shown in FIG. 4 can be used as a front gate electrode for the N-channel FET 30a and the P-channel FET 30b. The upper electrodes 34 and 34′ may be floating or may be used as back gates for dual operation control. The sources 35, 35′ and the upper P⁺ region of the isolated part of the P-well and the upper N⁺ region of the isolated part of the N-well may be connected to ground. In operation, a relatively high supply voltage of 3.6 V or more may be applied to the drains 36, 36′ and gate electrodes formed by parts of the semiconductor bulk substrate 31.

In all of the above-described examples, the semiconductor devices of the disclosure can be co-integrated with similar semiconductor devices wherein the semiconductor substrate does not comprise a gate electrode (is not operated as a gate electrode) but rather comprises a back gate (is operated as a back electrode). In these semiconductor devices that are not appropriate for high-voltage operation, the upper electrodes 14, 24, 24′, 34, 34′ illustrated in FIGS. 2, 3 and 4 form (are operated as) gate electrodes. In particular, the semiconductor devices shown in FIGS. 2, 3 and 4 may be co-integrated with semiconductor devices similar to the one shown in FIG. 1.

In conclusion, a measure to integrate high-voltage FTEs in the process flow of manufacturing usual low-voltage FDSOI FETs is provided. For the usual low-voltage FDSOI FETs, the semiconductor bulk substrate of the SOI substrate may be used for back biasing. The gate electrodes of these devices are formed above the SOI substrate and separated from the semiconductor layer of the SOI substrate by a gate dielectric. Contrary, the high-voltage FTEs comprise parts of the SOI substrate as front gate electrodes and the electrodes formed above the SOI substrate can be used for back-biasing. For the high-voltage FETs, the BOX layer of the SOI substrate functions as a gate dielectric and also electrically isolates the gate electrode comprised in the semiconductor bulk substrate. Thus, co-integration of manufacturing of the high-voltage FETs with the process flow of manufacturing the usual FDSOI FETs that are suitable for low-voltage operation only can be readily achieved without any need for additional masking and depositing steps.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1-31. (canceled)

32. A method, comprising
providing a silicon-on-insulator (SOI) substrate comprising a semiconductor bulk substrate, a buried oxide layer formed on said semiconductor bulk substrate and a semiconductor layer formed on said buried oxide layer, wherein a first transistor device defined in and on said SOI substrate includes a first gate insulation layer positioned on said semiconductor layer, a first upper gate electrode positioned on said first gate insulation layer, and a first lower gate electrode positioned in said semiconductor bulk substrate, and a second transistor device defined in said SOI substrate includes a second upper gate electrode positioned on said first gate insulation layer and a second lower gate electrode positioned in said semiconductor bulk substrate;
applying a first voltage to said first lower gate electrode; and
applying a second voltage less than said first voltage to said first upper gate electrode.

33. The method of claim 32, wherein said first transistor device further comprises first raised source and drain regions positioned over said semiconductor layer, and said second transistor device further comprises second raised source and drain regions positioned over said semiconductor layer.

34. The method of claim 32, wherein said first transistor device further comprises a first channel region positioned in said semiconductor layer, and said second transistor device further comprises a second channel region positioned in said semiconductor layer.

35. The method of claim 32, wherein said first transistor device includes a first source region and a first drain region and the method further comprises applying said first voltage to said first drain region.

36. The method of claim 35, further comprising applying said second voltage to said first source region.

37. The method of claim 32, wherein applying said second voltage comprises applying a floating voltage.

38. The method of claim 32, wherein applying said second voltage comprises applying a ground voltage.

39. The method of claim 32, further comprising:
applying a third voltage to said second lower gate electrode; and
applying a fourth voltage less than said third voltage to said second upper gate electrode.

40. The method of claim 39, wherein said first transistor device includes a first source region and a first drain region, said second transistor device includes a second source region and a second drain region, and the method further comprises:
applying said first voltage to said first drain region; and
applying said third voltage to said second drain region.

41. The method of claim 40, further comprising:
applying said second voltage to said first source region; and
applying said fourth voltage to said second source region.

42. The method of claim 40, wherein applying said second and fourth voltages comprises applying a floating voltage.

43. The method of claim 40, wherein applying said second and fourth voltages comprises applying a ground voltage.

44. A method, comprising
providing a silicon-on-insulator (SOI) substrate comprising a semiconductor bulk substrate, a buried oxide layer formed on said semiconductor bulk substrate and a semiconductor layer formed on said buried oxide layer, wherein a first transistor device defined in and on said SOI substrate includes a first gate insulation layer positioned on said semiconductor layer, a first upper gate electrode positioned on said first gate insulation layer, and a first lower gate electrode positioned in said semiconductor bulk substrate;
applying a first voltage to said first lower gate electrode; and
applying a second voltage less than said first voltage to said first upper gate electrode.

45. The method of claim 44, wherein said first transistor device includes a first source region and a first drain region, and the method further comprises applying said first voltage to said first drain region.

46. The method of claim 45, further comprising applying said second voltage to said first source region.

47. The method of claim 46, wherein applying said second voltage comprises applying a floating voltage.

48. The method of claim 46, wherein applying said second voltage comprises applying a ground voltage.

49. The method of claim 44, wherein applying said second voltage comprises applying a floating voltage.

50. The method of claim 44, wherein applying said second voltage comprises applying a ground voltage.
